(19) United States
(12) Patent Application Publication
(10) Pub. No.: US 2026/0206586 A1
(43) Pub. Date: Jul. 16, 2026

(54) Heat Dissipation Methods and Structures for Semiconductor Devices

(71) Applicant: Applied Materials, Inc., Santa Clara, CA (US)

(72) Inventors: Balasubramanian PRANATHARTHIHARAN, San Jose, CA (US); Siddarth KRISHNAN, San Jose, CA (US); Brian KIRKPATRICK, Sunnyvale, CA (US); Matthew O'LEARY, Missoula, MT (US); Hui Jae YOO, Tustin, CA (US); Baorui CHENG, Santa Clara, CA (US); Kashish SHARMA, Santa Clara, CA (US); Abhijit B. MALLICK, Fremont, CA (US); Veeraraghavan BASKER, Sunnyvale, CA (US); Karthik GUDA VISHNU, Milpitas, CA (US); Liu JIANG, Dublin, CA (US)

(21) Appl. No.: 19/273,572

(22) Filed: Jul. 18, 2025

Related U.S. Application Data
(60) Provisional application No. 63/743,846, filed on Jan. 10, 2025.

(51) Int. Cl. H01L 23/373; H01L 23/48

(52) U.S. Cl. CPC H10W 40/259; H10W 20/20

(57) ABSTRACT

A method of increasing thermal uniformity of a substrate incorporates high thermal conductivity material in place of shallow trench isolation (STI) dielectric material or interlayer dielectric (ILD) material on a backside of a thinned substrate. The method may comprise removing at least a portion of an STI dielectric material and/or ILD material and depositing a second dielectric material in place of the STI dielectric material that is removed. The second dielectric material has a higher thermal conductivity than the STI dielectric material. The removal may incorporate a wet or dry etch process that is selective to the STI dielectric material and/or the ILD material over other materials used in formation of semiconductor structures on a substrate.

### CROSS-REFERENCE TO RELATED APPLICATIONS

This application claims the benefit of U.S. provisional patent application Ser. No. 63/743,846, filed Jan. 10, 2025, which is herein incorporated by reference.

### FIELD

Embodiments of the present principles generally relate to semiconductor processing of semiconductor substrates.

### BACKGROUND

Active semiconductor devices generate heat that must be dissipated to maintain reliability of the structure and optimal performance. As device technology advances, the device size decreases, and more of the devices can be grouped together in a given area for high performance and processing speeds, increasing device density and creating hotspots. One traditional technique to mitigate the hotspots is to impose design rules that attempt to keep active semiconductor devices spread apart to ensure a more uniform dissipation of heat across a substrate or chip. The inventors have observed, however, that such design constraints often lead to reduced performance of the semiconductor devices and increased manufacturing and design costs.

Accordingly, the inventors have provided methods and structures which provide more uniform heat dissipation without the need for design rules that force an even distribution of active substrate devices across a substrate in order to reduce hotspots.

### SUMMARY

Methods and structures for improving heat dissipation of semiconductor devices are provided herein.

In some embodiments, a method of increasing thermal uniformity of a substrate may comprise removing at least a portion of a shallow trench isolation (STI) dielectric material and depositing a second dielectric material in place of the at least a portion of the STI dielectric material that is removed, wherein the second dielectric material has a thermal conductivity higher than the STI dielectric material.

In some embodiments, the method may further include a liner that is deposited prior to depositing the second dielectric material if an STI liner material is removed with the STI dielectric material and an STI liner material or a bottommost portion of the second dielectric material that is deposited with grain orientations perpendicular to a deposition surface within +/−10 degrees, a side of the substrate with the second dielectric material that is bonded to a wafer, a chip, or a supplemental substrate, an STI dielectric material that is removed using a wet etching process or a dry etching process that is selective to the STI dielectric material over other materials exposed during etching of the substrate, removal of the at least a portion of the STI dielectric material that is selective to the STI dielectric material over interlayer dielectric (ILD) materials, STI liner materials, and contact materials, removal of the at least a portion of the STI dielectric material that is selective to the STI dielectric material over other materials that include interlayer dielectric (ILD) materials, STI liner materials, contact materials, silicon nitride (SiN) based materials, silicon oxycarbonitride (SiOCN) based materials, silicon germanium (SiGe) based materials, and silicon phosphide (SiP) based materials, an interlayer dielectric (ILD) material that is removed along with the STI dielectric material using a wet etching process or a dry etching process that is selective to the STI dielectric material and the ILD material over other materials exposed during etching of the substrate, removal of the at least a portion of the STI dielectric material that is selective to the STI dielectric material and interlayer dielectric (ILD) materials over STI liner materials and contact materials, removal of the at least a portion of the STI dielectric material that is selective to the STI dielectric material and interlayer dielectric (ILD) materials over STI liner materials, contact materials, silicon nitride (SiN) based materials, silicon oxycarbonitride (SiOCN) based materials, silicon germanium (SiGe) based materials, and silicon phosphide (SiP) based materials, a liner that is deposited on the substrate prior to depositing the second dielectric material or an interlayer dielectric (ILD) material on the substrate to remove selectivity of a wet etching process or a dry etching process over silicon nitride (SiN) based materials, silicon oxycarbonitride (SiOCN) based materials, silicon germanium (SiGe) based materials, and silicon phosphide (SiP) based materials, a second dielectric material that is aluminum nitride-based material, diamond-based material, or boron nitride-based material, a second dielectric material that has a thermal conductivity of at least 50 W/mK, a second dielectric material that is used in addition to through silicon vias (TSV) or TSV-like structures formed on the substrate, interposers, carrier wafers, or supplemental wafers, or used as inter-die gapfill material to dissipate heat from the substrate, a second dielectric material that is deposited at a temperature of 400 degrees Celsius or less, and/or a second dielectric material that has a thermal conductivity of 10× or greater, where X is a thermal conductivity of the STI dielectric material.

In some embodiments, a semiconductor structure may comprise one or more contacts electrically connected to one or more source/drains of one or more transistors and a dielectric material that surrounds the one or more contacts where the dielectric material has a thermal conductivity of at least 50 W/mK. In some embodiments, the semiconductor structure may further include a dielectric material that is aluminum nitride-based material, diamond-based material, or boron nitride-based material, a dielectric material that has a thermal conductivity of at least 100 W/mK, and/or a dielectric material that is configured to provide shallow trench isolation for the one or more transistors.

In some embodiments, the semiconductor structure may further include a dielectric material that is aluminum nitride-based material, diamond-based material, or boron nitride-based material, a dielectric material that has a thermal conductivity of at least 100 W/mK, and/or a dielectric material that has an initial bottommost portion with grain orientations perpendicular to an underlying material interface within +/−10 degrees and is configured to provide shallow trench isolation for the one or more transistors.

In some embodiments, a non-transitory, computer readable medium having instructions stored thereon that, when executed, cause a method for increasing thermal uniformity of a substrate, to be performed, the method may comprise removing at least a portion of a shallow trench isolation (STI) dielectric material and depositing a second dielectric material in place of the at least a portion of the STI dielectric material that is removed where a liner layer is deposited prior to depositing the second dielectric material if an STI liner material is removed with the STI dielectric material, the liner layer or a bottommost portion of the second dielectric material is deposited with grain orientations perpendicular to a deposition surface within +/−10 degrees, and the second dielectric material has a thermal conductivity higher than the STI dielectric material.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a method of increasing thermal uniformity of a substrate using, for example, backside processing of a substrate in accordance with some embodiments of the present principles.

FIG. 2 depicts a cross-sectional view of a flipped substrate with a semiconductor structure with contacts and dielectric isolation material surrounding the contacts in accordance with some embodiments of the present principles.

FIG. 3 depicts a cross-sectional view of a flipped substrate with a semiconductor structure with contacts after removal of the dielectric isolation material surrounding the contacts in accordance with some embodiments of the present principles.

FIG. 4 depicts a cross-sectional view of a flipped substrate with a semiconductor structure with contacts after depositing high thermal conductivity material on a second side of the substrate in accordance with some embodiments of the present principles.

FIG. 5 depicts a cross-sectional view of a flipped substrate with a semiconductor structure with contacts after planarizing the high thermal conductivity material on a second side of the substrate to expose contacts and/or vias in accordance with some embodiments of the present principles.

FIG. 6 depicts a cutaway of an isometric view of a flipped substrate with semiconductor structures with contacts after depositing and planarizing the high thermal conductivity material on a second side of the substrate to expose the contacts in accordance with some embodiments of the present principles.

FIG. 7 depicts a bottom-up view of a flipped substrate with semiconductor structure with contacts after planarizing the high thermal conductivity material on a second side of the substrate to expose the contacts and/or in accordance with some embodiments of the present principles.

FIG. 8 depicts a cross-sectional view of a flipped substrate with a semiconductor structure with first and second interfaces in accordance with some embodiments of the present principles.

FIG. 9 depicts cross-sectional views of a grain orientation process performed on a substrate in accordance with some embodiments of the present principles.

FIG. 10 is a cross-sectional view of a substrate with layers deposited by the grain orientation process in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and structures herein mitigate localized temperature hotspots for semiconductor devices on a substrate. High thermal conductivity materials are integrated into semiconductor device formation process flows to ensure a more uniform temperature across the device without requiring semiconductor device separation design rules. In some embodiments, isolation material used during the formation of a device is removed and replaced with high thermal conductivity material, allowing for more uniform heat dissipation across the device substrate, significantly reducing or eliminating temperature hotspots while still providing shallow trench isolation. The approach permits high performance design layouts while increasing reliability through superior heat removal. In some embodiments, the high thermal conductivity materials may surround active devices to increase direct heat transfer from the active device into the high thermal conductivity materials. The high thermal conductivity materials can be bonded to other materials or heatsinks and the like to further transfer the heat away from the substrate and devices. The present techniques can be used as the sole means of heat dissipation or used in conjunction with other heat transfer processes such as using thermal path vias or even signal vias and similar structures to dissipate heat from the substrate. The present techniques also have the advantage of being solid state with no moving parts or other complexities such as, for example, use of fans for air cooling or use of liquid piping for liquid cooling, reducing costs while increasing circuit performance and reliability.

Currently, high performance computing is significantly expanding, driven by artificial intelligence and machine learning. Chip performance is doubling every 1.2 years, while power efficiency only doubles every 2.2 years. The slower progression in power efficiency means that the chip performance increases lead to higher temperatures and heat dissipation issues that are not easily overcome. Current heat dissipation solutions may be able to handle 700 watts to 1000 watts per chip (which is approximately 100 square centimeters per chip), but the current maximum heat dissipation capabilities are limited by the presence of temperature hot spots. Hot spots are created by nonuniform circuit layouts that are typically utilized to maximize chip performance. Implementing circuit layout and performance design rules to avoid hot spots usually leads to degraded chip performance.

Some traditional solutions use heat sinks built into a chip package that in turn uses heat fins or pins to transfer the heat to air or liquid moving across the surface. The traditional solutions mitigate heat dissipation to some extent but also limit the chip design layout in order to prevent the creation of hot spots. Typical heat dissipation methods exist outside of chip manufacturing, at the package level, and typically exist as “add-on” or “bolt-on” hardware. The present techniques disclosed herein address the hot spots within a chip manufacturing setting prior to, or early within the bonding processes. The present techniques enable cooling or heat dissipation closer to the source of the hot spots such as directly adjacent active semiconductor devices and the like, not previously achievable.

Several process integration flows within semiconductor manufacturing utilize fusion (single material) or hybrid bonding (multiple different materials) to attach a supplemental wafer to a primary device wafer. With the present techniques, isolation materials used during formation and/or integration on the primary die or substrate are replaced with a high thermal conductivity dielectric material. Thus, the hot spots are mitigated within the chip manufacturing setting prior to the bonding processes. The isolation materials can be accessed and selectively removed during manufacturing flows (e.g., after backgrinding of the substrate, etc.). The high thermal conductivity materials that replace the isolation materials can be used in conjunction with signal and heat dissipation TSV-like structures to conduct heat out of the chip or substrate. Transferring heat does not prevent the signal TSVs from performing a primary function, electrically connecting primary and supplemental chips and the like. Thus, the present techniques can be used as a stand-alone heat dissipation strategy or as an additive method in conjunction with added heat transfer devices or other heat dissipative features on, for example but not limited to, an interposer, a carrier wafer, a supplemental wafer, and/or as an interdie gapfill material. The present techniques provide a total solution for heat dissipation by increasing the uniformity of heat distribution regardless of the chip layout (i.e., no hot spots).

The present techniques leverage structure that was previously created during device integration and transforms structure function by replacing the original structure material or materials to perform both the original electrical isolation function and to also conduct heat. In some embodiments, the present techniques can be used to replace isolation material such as shallow trench isolation (STI) material and/or interlayer dielectric (ILD) material and the like used in forming, for example, transistor structures. The STI material completely surrounds the transistors to electrically isolate the different switches. The construction technique is used whether the transistor structure is, but not limited to, a planar complementary metal-oxide-semiconductor (CMOS) transistor, a fin field effect transistor (FinFET), a gate-all-around (GAA) transistor, and/or a complementary field effect transistor (CFET) integration and the like. All wafer bonding integrations require the primary die to be thinned. The thinning or backgrinding can leave the bottom of the STI material on a primary die exposed. Once exposed, the STI material can be replaced with a high thermal heat transfer dielectric such as, but not limited to, aluminum nitride (AlN) based materials, diamond-based materials, and/or boron nitride (BN) based materials, and the like, thereby providing a path to transfer heat uniformly across the die. Some of the replacement STI dielectric materials may require a liner and/or barrier to aid in electrical isolation of the semiconductor devices as discussed below. Essentially, in some embodiments, the STI and/or ILD materials serve as sacrificial dielectric materials that are replaced with high thermal heat transfer dielectric materials after transistor formation. The high thermal heat transfer dielectric material functions as heat dissipation material and shallow trench isolation material.

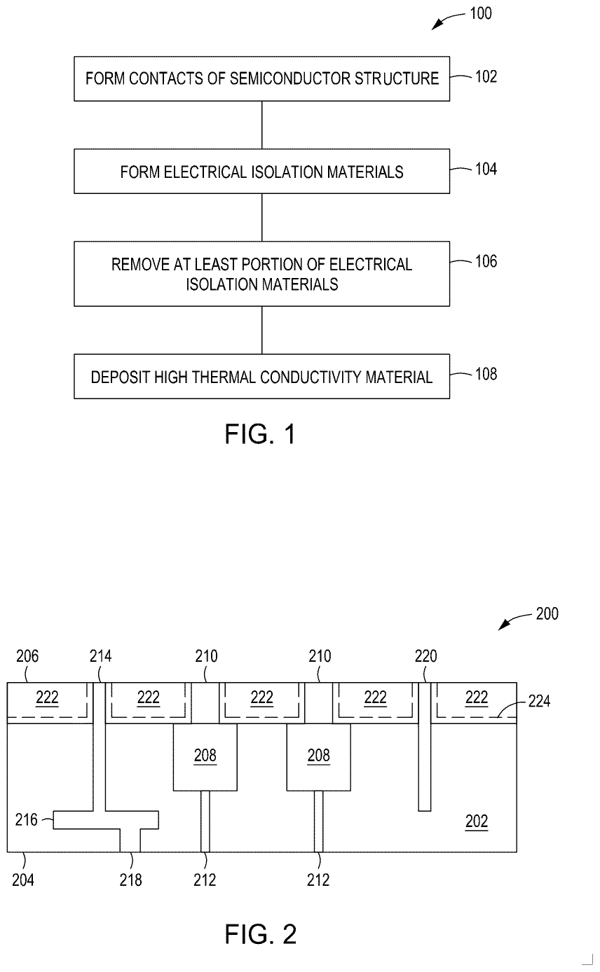

FIG. 1 is a method 100 of increasing thermal uniformity of a substrate with semiconductor structures. In block 102, a semiconductor structure 208 has been formed on a substrate 202 with contacts 210 for the semiconductor structure 208 exposed on a second side 206 (backside) of the substrate 202 as depicted in a view 200 of FIG. 2. The method 100 may be used to enhance heat uniformity on either side (frontside or backside) of a substrate. Processing is depicted for the backside in the examples used herein solely for the sake of brevity but is not meant to be limiting. In some embodiments, the semiconductor structure 208 may be, for example but not limited to, a transistor with one or more contacts electrically connected to source/drains of the transistor and the like. The semiconductor structure 208 may also have electrical connections 212 exposed on a first side 204 (topside) of the substrate 202. In some embodiments, electrical connection TSVs 214 may also be present on the second side 206 (or the first side 204) and may provide connections, for example, to redistribution layers 216 or connections 218 on the first side 204. In some embodiments, the electrical connection TSVs 214 may also be used in conjunction with the present techniques to dissipate heat from nearby semiconductor structures as well as performing electrical connection functions. In some embodiments, heat dissipation TSVs 220 may also be used in conjunction with the present techniques to function solely as heat dissipation structures without any electrical connection function.

In block 104, electrical isolation material 222 has been formed on the substrate 202 to facilitate in electrically isolating the semiconductor structures 208 and/or contacts 210 and the like as depicted in FIG. 2. In some embodiments, the semiconductor structure 208 may be, but is not limited to, a transistor structure that is, for example, a planar CMOS transistor, a FinFET, a GAA transistor, and/or a CFET and the like. Materials used for the electrical isolation material 222 are selected based on the type of structure and the material's ability to be formed and used during the formation of the semiconductor structure 208. Replacement materials discussed below for use as high thermal conductivity materials may not be able to endure the same process conditions as the electrical isolation material 222. For example, process temperatures may alter the thermal conductivity value of the high thermal conductivity material, negating the benefit of replacing the electrical isolation material 222 with high conductivity materials at the formation stage of the semiconductor structure 208. The high thermal conductivity material may not also have a desired deposition or removal selectivity compared to the electrical isolation material 222, making the high thermal conductivity material incompatible with the semiconductor structure formation process. In such instances, the electrical isolation material 222 may be used as a sacrificial dielectric material that is replaced, in whole or in part with a high thermal heat transfer dielectric material after the transistor formation.

In some embodiments, the contacts 210 are formed prior to the deposition of the electrical isolation material 222. In some embodiments, the contacts 210 are formed after the deposition of the electrical isolation material 222. In some embodiments, the electrical isolation material 222 may include STI dielectric materials and/or ILD materials and the like. The STI dielectric material and/or ILD material of the electrical isolation material 222 serve as sacrificial dielectric material to enable formation of the transistor using traditional processes. For example, the STI dielectric materials may include, but are not limited to, high density plasma (HDP) oxide with or without carbon doping and the like. In some examples, the STI dielectric materials may have a thermal conductivity of only approximately 45 W/mK or less. In some embodiments of the present techniques, a barrier or liner 224 may be deposited on the substrate 202 prior to the deposition of the electrical isolation material 222. The liner 224 may serve multiple functions—one—as an etch stop barrier to negate the necessity of etching selectivity of materials over other materials (discussed below) to simplify the etching process, two—as an enhanced electrical isolation barrier to supplement the thermal conductivity material (discussed below) that may not provide enough electrical isolation of the semiconductor structure 208 once the electrical isolation material 222 is removed (discussed next), and/or three—a film to enhance or smooth the interface of the semiconductor surface, thereby reducing local areas of high physical and electrical stress. The liner 224 is optional and may not be present in some embodiments.

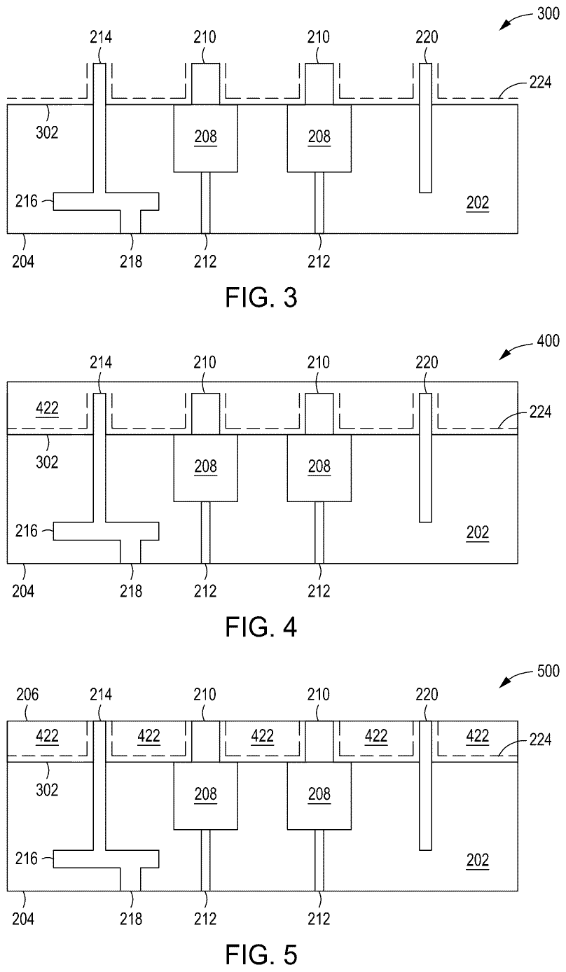

In block 106, at least a portion of the electrical isolation material 222 is sacrificed or removed from the second side 206 of the substrate 202 to expose a surface 302 of the second side 206 as depicted in a view 300 of FIG. 3. During traditional formation of the substrate 202, the second side 206 of the substrate 202 is thinned exposing the electrical isolation material 222, contacts 210, and vias, etc. The thinning and exposure of the materials on the second side 206 of the substrate 202 allows for insertion in the integration flow of selective etching processes for removing the electrical isolation material 222. In preferred etching processes, the selectivity ratio allows <2 nm or less in thickness of non-targeted materials to be removed while removing the targeted material or materials. The amount of selectivity and the selectivity over which materials may be altered is based on the type and construction of the semiconductor structure 208 and also based on what materials will be exposed by removal of STI materials and/or ILD materials and the like. In some embodiments, the selectivity ratio may be from approximately 50:1 to approximately 300:1 or higher for the removal of the targeted material over the non-targeted material. The selectivity ratio may also be affected by dopants in the materials. The inventors have found that in typical semiconductor structures, the more sensitive materials (e.g., silicon or silicon germanium, etc.) are only briefly exposed during the end stages (over etching steps) of the etching process and are not significantly impacted.

In some embodiments, STI dielectric material of the electrical isolation material 222 may be removed using a wet chemical etching process that is selective to STI dielectric material over ILD material, STI liner material, and contact material (including via material when present). Wet chemical etching processes are self-limiting. In some embodiments, STI dielectric material of the electrical isolation material 222 may be removed using a wet chemical etching process that is selective to STI dielectric material over ILD material, STI liner material, contact material (including via material when present), silicon nitride (SiN) based materials, silicon oxycarbonitride (SiOCN) based materials, silicon germanium (SiGe) based materials, and silicon phosphide (SiP) based materials and the like that may have been used during the formation of the semiconductor structure 208 and contacts 210 and the like. One skilled can appreciate that semiconductor structures may be formed using any number of materials and types and that selectivity of the etching processes used in the present techniques are not limited to the foregoing listing of materials.

In some embodiments, STI dielectric material of the electrical isolation material 222 may be removed using a dry chemical etching process that is selective to STI dielectric material over ILD material, STI liner material, and contact material (including via material when present). Dry chemical etching processes are not self-limiting and an endpoint detection process such as, but not limited to, detection of platinum, nickel, or cobalt in the plasma or detection of the absence of oxide and/or other elements may be used to halt the dry etching process. Detection can also be used to switch to a higher selectivity chemistry for a soft etch stop. In some embodiments, STI dielectric material of the electrical isolation material 222 may be removed using a dry chemical etching process that is selective to STI dielectric material over ILD material, STI liner material, contact material (including via material when present), SiN based materials, SiOCN based materials, SiGe based materials, and SiP based materials and the like that may have been used during the formation of the semiconductor structure 208 and contacts 210 and the like. One skilled in the art can appreciate that semiconductor structures may be formed using any number of materials and types and that selectivity of the etching processes used in the present techniques are not limited to the foregoing listing of materials.

In some embodiments, STI dielectric material and ILD material of the electrical isolation material 222 may be removed using a wet chemical etching process that is selective to STI dielectric material and ILD material over STI liner material and contact material (including via material when present). In some embodiments, STI dielectric material and ILD material of the electrical isolation material 222 may be removed using a wet chemical etching process that is selective to STI dielectric material and ILD material over STI liner material, contact material (including via material when present), SiN based materials, SiOCN based materials, SiGe based materials, and SiP based materials and the like that may have been used during the formation of the semiconductor structure 208 and contacts 210 and the like. One skilled in the art can appreciate that semiconductor structures may be formed using any number of materials and types and that selectivity of the etching processes used in the present techniques are not limited to the foregoing listing of materials.

In some embodiments, STI dielectric material and ILD material of the electrical isolation material 222 may be removed using a dry chemical etching process that is selective to STI dielectric material and ILD material over STI liner material and contact material (including via material when present). In some embodiments, STI dielectric material and ILD material of the electrical isolation material 222 may be removed using a dry chemical etching process that is selective to STI dielectric material and ILD material over STI liner material, contact material (including via material when present), SiN based materials, SiOCN based materials, SiGe based materials, and SiP based materials and the like that may have been used during the formation of the semiconductor structure 208 and contacts 210 and the like. One skilled in the art can appreciate that semiconductor structures may be formed using any number of materials and types and that selectivity of the etching processes used in the present techniques are not limited to the foregoing listing of materials.

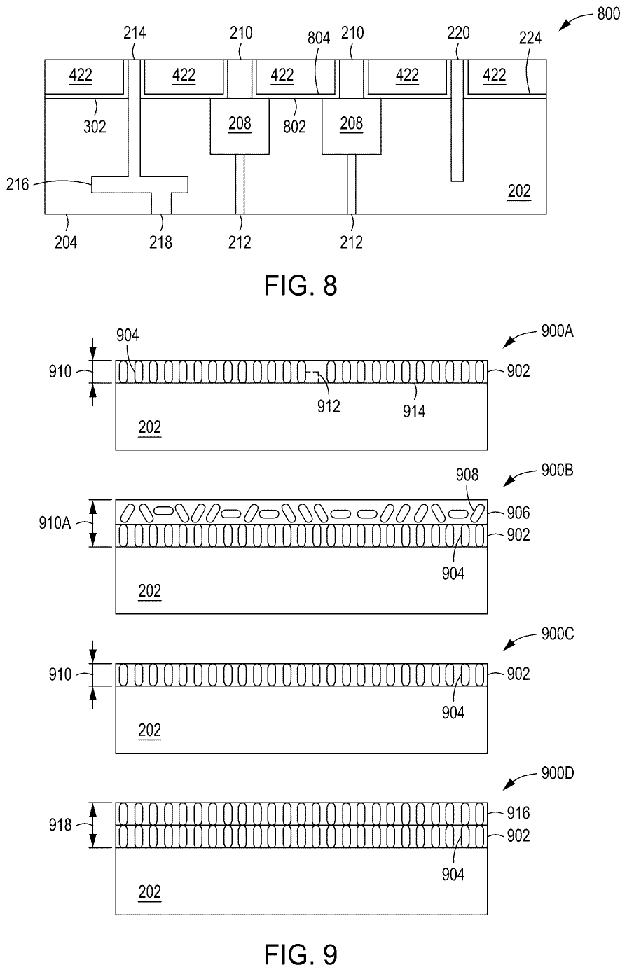

In some embodiments, instead of depositing the liner 224 prior to the deposition of the electrical isolation material 222, the liner 224 can be deposited after removal of at least a portion of the electrical isolation material 222 (e.g., after removal of the STI dielectric material and/or the ILD material, etc.). The liner 224 is optional and may not be present. The liner 224, when deposited after removal of at least a portion of the electrical isolation material 222, serves as an enhanced electrical isolation barrier to supplement the high thermal conductivity material (discussed below) that may not provide enough electrical isolation of the semiconductor structure 208 once at least a portion of the electrical isolation material 222 is removed. In some embodiments, the liner 224 may be deposited using a grain orientation deposition process to further enhance the effective thermal conductivity and is discussed below in detail with reference to FIGS. 8-10.

In block 108, after removal of at least a portion of the electrical isolation material 222, a high thermal conductivity material 422 is deposited on the surface 302 of the second side 206 of the substrate 202 as depicted in a view 400 of FIG. 4. The high thermal conductivity material 422 serves as an STI dielectric material for the transistors as well as a heat spreader. In some embodiments, an enhanced liner layer (e.g., the liner 224) with increased electrical isolation properties may be deposited prior to the deposition of the high thermal conductivity material 422 when the high thermal conductivity material 422 has lower electrical isolation properties than the sacrificial dielectric material that is removed. In such instances, the liner and the high thermal conductivity material serve as STI dielectric material. In some embodiments, the deposition of the high thermal conductivity material 422 is a blanket type deposition. In some embodiments, the deposition process may be a plasma enhanced chemical vapor deposition (PECVD) process, an HDP process, a metalorganic CVD (MOCVD) process, and/or an atomic layer deposition (ALD) process or plasma enhanced ALD (PEALD) process, and the like. In some embodiments, an initial bottommost layer of the high thermal conductivity material 422 may be deposited using a grain orientation process to further enhance the effective thermal conductivity as discussed below with reference to FIGS. 8-10.

The high thermal conductivity material 422 is deposited at a temperature of approximately 400 degrees Celsius or less for substrates with copper and at a temperature of approximately 600 degrees Celsius or less for substrates with aluminum instead of copper. In some embodiments, the high thermal conductivity material 422 may be AlN based material, diamond-based material, BN based material, and the like. In some embodiments, the high thermal conductivity material 422 has a thermal conductivity value of approximately 100 W/mK or greater. In some embodiments, the high thermal conductivity material 422 has a thermal conductivity value of approximately 100 W/mK to 1000 W/mK. In some embodiments, the high thermal conductivity material 422 has a thermal conductivity value of approximately 1000 W/mK or greater.

Some high thermal conductivity materials such as, but not limited to, aluminum nitride have thermal conductivity values that change with the temperature at which the material is deposited. The inventors have found that aluminum nitride deposited at approximately 400 degrees Celsius or less can be used as the high thermal conductivity material 422 with better thermal dissipation characteristics. In some embodiments, the aluminum nitride can be deposited at approximately 600 degrees Celsius or less if the thermal budget of the substrate is not exceeded. Aluminum nitride has less columnar grain boundaries the higher the deposition temperature. Minimization of grain boundaries in the high thermal conductivity material 422 reduces leakage currents. Preferably, the high thermal conductivity material has large columnar grains which yield less grain boundaries and less leakage current paths. In some embodiments, the high thermal conductivity material 422 may have a thermal conductivity value of 10X or more, where X is the thermal conductivity value of the electrical isolation material 222. In some embodiments, the high thermal conductivity material 422 may have a thermal conductivity value of up to 1000X. A planarization process is then performed to expose the contacts 210 and vias on the second side 206 of the substrate 202 as depicted in a view 500 of FIG. 5. In some embodiments, the planarization process is a chemical mechanical polishing (CMP) process and/or a plasma planarization process using planarizing photoresist and the like.

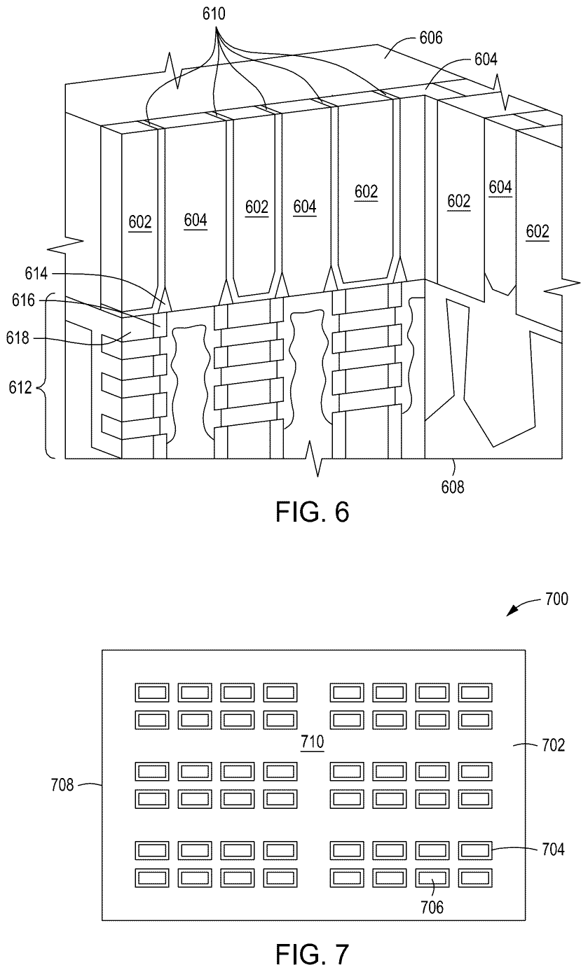

FIG. 6 is a cutaway view 600 of a flipped substrate with semiconductor structures 612 with contacts 604 after depositing and planarizing the high thermal conductivity material 602 on the backside 606 of the substrate 608 to expose the contacts 604. In the example of FIG. 6, the present techniques have been used to form the GAA transistors to create semiconductor structures 612 on the substrate 608 with high thermal uniformity. In the example, a high k dielectric liner 610 (i.e., liner 224) has been incorporated to provide added electrical isolation between the contacts 604. During formation of the high thermal conductivity material 602 and the high k dielectric liner 610, the etching process to remove the STI dielectric material and the ILD material had to take into account additional semiconductor structure materials for selectivity such as a silicon nitride film 614, a dielectric film 616, and a silicon germanium/silicon film 618. Each semiconductor structure may have different materials, and the etching processes can be easily adjusted accordingly due to the flexibility afforded by the present techniques. In addition, if the liner is formed prior to the etching processes, the selectivity can be adjusted to the liner material instead of a multitude of underlying films that need to be accounted for if the liner is absent, making the process more efficient and less costly.

The present techniques can allow traditional heat sink technology to reach a much higher performance in W/cm² design, possibly reaching 2000 W/chip or higher using the uniform thermal distribution. As depicted in a bottom-up view 700 of FIG. 7, a substrate 708 has incorporated high thermal conductivity material 710 on a backside 702 of the substrate 708. The high thermal conductivity material 710 surrounds each of the contacts 706. The contacts 706 may or may not have a barrier or liner 704 directly adjacent to provide electrical isolation. The high thermal conductivity material 710 permits semiconductor structures such as, but not limited to, transistors and the like to be positioned in close proximity and grouped according to performance requirements rather than for thermal dissipation performance. The high thermal conductivity material 710 dissipates the heat from grouped transistors throughout the substrate 708 in a uniform fashion. As the present techniques can be performed prior to bonding, the high thermal conductivity material 710 can be bonded to another substrate such as a carrier substrate and/or a heatsink and the like to further assist in dissipating the heat from the semiconductor structures.

The inventors have also discovered that the effective thermal conductivity of a structure incorporating the liner 224 and/or the high thermal conductivity material 422 can be further enhanced by reducing the thermal resistance of a first interface 802 between active heat producing elements and/or materials and the liner 224 as well as a second interface 804 between the liner 224 and the high conductivity material 422 as depicted in a view 800 of FIG. 8. If no liner 224 is used or if the liner 224 has been previously deposited, the heat transfer can still be improved by enhancing the second interface 804 between the high thermal conductivity material 422 and any underlying materials or liner. Randomized grain orientation at the first interface 802 and the second interface 804 causes increased thermal resistance into the high thermal conductivity material 422. By using a grain orientation process to produce grain orientations that are perpendicular to the surfaces that the deposition material is deposited on, the thermal conductivity of the interface can be increased from 2N to 10N or more, where N is the thermal conductivity of an interface without using the grain orientation processes described herein (i.e., randomized grain orientation depositions). The grain orientation process can be used for deposition of the entire thickness of the liner 224 and/or for an initial bottommost deposition layer for the high thermal conductivity material 422.

The grain orientation process is based on a deposition-etch process that may include one or more cycles of deposition and etch to reach a desired thickness. As depicted in a view 900 of FIG. 9, when a material is deposited, the processing conditions, for example, rate, electrical bias, temperature, and the like are optimized for the initial grains to have an approximately perpendicular orientation 912 (oriented approximately 90 degrees to surface (plus or minus approximately 10 degrees from perpendicular)) to the surface 914 on which the material is deposited. As the deposited material increases in thickness 910, the grain orientation becomes randomized, increasing the thermal resistance of the deposited layer. A first layer 902 represents deposition with grains 904 with predominantly perpendicular orientations. As the thickness 910A increases, the grain orientation 908 as depicted in a view 900B of FIG. 9 becomes a randomized grain layer 906. The grain orientation process then uses an etch process to remove the randomized grain layer 906 as depicted in a view 900C of FIG. 9. A second deposition process of the grain orientation process is then used to deposit more perpendicular grain material in a second layer 916 as depicted in a view 900D of FIG. 9. The thickness 918 of perpendicular grain material includes the thickness of the first layer 902 and the second layer 916. The deposition-etch cycles of the grain orientation process can be repeated any number of times to reach a desired thickness of perpendicularly oriented grains. The grain orientation process may include a plasma enhanced chemical vapor deposition (PECVD) process and/or a plasma enhanced atomic layer deposition (PEALD) process and the like.

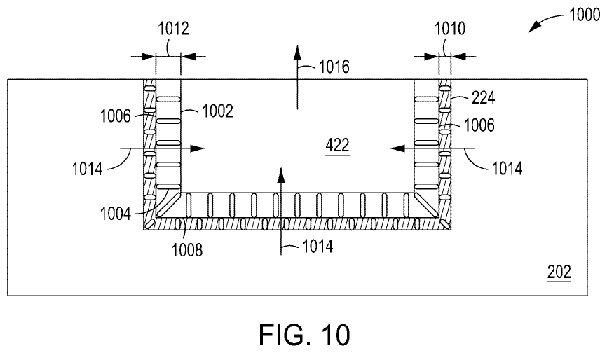

The grain orientation process may be used to deposit the entire thickness 1010 of the liner 224 and/or may be used to deposit an initial layer 1002 for the high thermal conductivity material 422 as depicted in a view 1000 of FIG. 10. In some embodiments, the entire thickness 1010 of the liner 224 may be from greater than zero to approximately 2 nm. The grain orientation process is conformal in nature, and the grains 1004 will be oriented perpendicular to the surface on which the initial layer 1002 is deposited on. In other words, the grain orientation on the sidewalls 1006 will be approximately horizontal in nature and the grain orientation on the bottom 1008 will be approximately vertical in nature. Deposition of the remaining high thermal conductivity material 422 will have more randomized grain orientations to reduce leakage in the high thermal conductivity material 422. In the example of FIG. 10, the liner 224 has been deposited using the grain orientation process for the entire thickness 1010 of the liner 224 to further enhance thermal conductivity. The thickness 1012 of the initial layer 1002 of the high thermal conductivity material 422 may be from greater than zero to approximately 2 nm. The thicknesses of the liner 224 and the initial layer 1002 are not drawn to scale in order to depict the different layers and grain orientations more easily. In the example, the alignment of the grains facilitates in drawing the heat 1014 from active semiconductor structures and the like into the high thermal conductivity material 422 with substantially less thermal resistance, from 2N to 10N or more over grains with random orientations at the layer interfaces. The high thermal conductivity material 422 can then draw the heat 1016 from the materials and/or devices/structures on the substrate 202 to the environment and/or to a heatsink and the like.

The cavities in which the liner 224 and the high thermal conductivity material 422 is deposited into may prove challenging for deposition due to the high aspect ratios with narrow openings. ALD processes (including CVD processes) are better suited for conformal depositions than physical vapor deposition (PVD) processes. As such, deposition processes for boron-based materials and/or diamond-based materials (e.g., carbon-based materials, etc.) and the like can be more readily deposited in nooks and crannies of cavities using ALD based processes than aluminum nitride-based materials which require PVD processes. Use of aluminum nitride materials would also require a separate PVD chamber for deposition whereas ALD-based deposition materials can use the same chamber for liner deposition and high thermal conductivity material deposition as well as the grain orientation processes, saving time and increasing throughput. The grain orientation process can be used solely for the high thermal conductivity material 422 or solely for the liner 224 or for both the high thermal conductivity material 422 and the liner 224. The grain orientation process is performed at a temperature of approximately 400 degrees Celsius or less in back end of line (BEOL) processes to stay with the thermal budget of semiconductor structures formed on the substrate.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method of increasing thermal uniformity of a substrate, comprising:
removing at least a portion of a shallow trench isolation (STI) dielectric material; and
depositing a second dielectric material in place of the at least a portion of the STI dielectric material that is removed, wherein the second dielectric material has a thermal conductivity higher than the STI dielectric material.

2. The method of claim 1, wherein a liner is deposited prior to depositing the second dielectric material if an STI liner material is removed with the STI dielectric material and wherein an STI liner material or a bottommost portion of the second dielectric material is deposited with grain orientations perpendicular to a deposition surface within +/−10 degrees.

3. The method of claim 1, wherein a side of the substrate with the second dielectric material is bonded to a wafer, a chip, or a supplemental substrate.

4. The method of claim 1, wherein the STI dielectric material is removed using a wet etching process or a dry etching process that is selective to the STI dielectric material over other materials exposed during etching of the substrate.

5. The method of claim 1, wherein removal of the at least a portion of the STI dielectric material is selective to the STI dielectric material over interlayer dielectric (ILD) materials, STI liner materials, and contact materials.

6. The method of claim 1, wherein removal of the at least a portion of the STI dielectric material is selective to the STI dielectric material over other materials that include interlayer dielectric (ILD) materials, STI liner materials, contact materials, silicon nitride (SiN) based materials, silicon oxycarbonitride (SiOCN) based materials, silicon germanium (SiGe) based materials, and silicon phosphide (SiP) based materials.

7. The method of claim 1, wherein an interlayer dielectric (ILD) material is removed along with the STI dielectric material using a wet etching process or a dry etching process that is selective to the STI dielectric material and the ILD material over other materials exposed during etching of the substrate.

8. The method of claim 1, wherein removal of the at least a portion of the STI dielectric material is selective to the STI dielectric material and interlayer dielectric (ILD) materials over STI liner materials and contact materials.

9. The method of claim 1, wherein removal of the at least a portion of the STI dielectric material is selective to the STI dielectric material and interlayer dielectric (ILD) materials over STI liner materials, contact materials, silicon nitride (SiN) based materials, silicon oxycarbonitride (SiOCN) based materials, silicon germanium (SiGe) based materials, and silicon phosphide (SiP) based materials.

10. The method of claim 1, wherein a liner is deposited on the substrate prior to depositing the second dielectric material or an interlayer dielectric (ILD) material on the substrate to remove selectivity of a wet etching process or a dry etching process over silicon nitride (SiN) based materials, silicon oxycarbonitride (SiOCN) based materials, silicon germanium (SiGe) based materials, and silicon phosphide (SiP) based materials.

11. The method of claim 1, wherein the second dielectric material is aluminum nitride-based material, diamond-based material, or boron nitride-based material.

12. The method of claim 1, wherein the second dielectric material has a thermal conductivity of at least 50 W/mK.

13. The method of claim 1, wherein the second dielectric material is used in addition to through silicon vias (TSV) or TSV-like structures formed on the substrate, interposers, carrier wafers, or supplemental wafers, or used as inter-die gapfill material to dissipate heat from the substrate.

14. The method of claim 1, wherein the second dielectric material is deposited at a temperature of 400 degrees Celsius or less.

15. The method of claim 1, wherein the second dielectric material has a thermal conductivity of 10X or greater, where X is a thermal conductivity of the STI dielectric material.

16. A semiconductor structure, comprising:
one or more contacts electrically connected to one or more source/drains of one or more transistors; and
a dielectric material that surrounds the one or more contacts, wherein the dielectric material has a thermal conductivity of at least 50 W/mK.

17. The semiconductor structure of claim 16, wherein the dielectric material is aluminum nitride-based material, diamond-based material, or boron nitride-based material.

18. The semiconductor structure of claim 16, wherein the dielectric material has a thermal conductivity of at least 100 W/mK.

19. The semiconductor structure of claim 16, wherein the dielectric material having an initial bottommost portion with grain orientations perpendicular to an underlying material interface within +/−10 degrees and is configured to provide shallow trench isolation for the one or more transistors.

20. A non-transitory, computer readable medium having instructions stored thereon that, when executed, cause a method for increasing thermal uniformity of a substrate, to be performed, the method comprising:
removing at least a portion of a shallow trench isolation (STI) dielectric material; and
depositing a second dielectric material in place of the at least a portion of the STI dielectric material that is removed, wherein a liner layer is deposited prior to depositing the second dielectric material if an STI liner material is removed with the STI dielectric material, wherein the liner layer or a bottommost portion of the second dielectric material is deposited with grain orientations perpendicular to a deposition surface within +/−10 degrees, and wherein the second dielectric material has a thermal conductivity higher than the STI dielectric material.
